(19) United States
(12) Patent Application Publication
(10) Pub. No.: US 2025/0210940 A1
(43) Pub. Date: Jun. 26, 2025

(54) SEMICONDUCTOR LASER ELEMENT

(71) Applicant: NICHIA CORPORATION, Anan-shi (JP)

(72) Inventors: Ryohei HIROSE, Itano-gun (JP); Shingo MASUI, Tokushima-shi (JP); Hisashi OGAWA, Yokohama-shi (JP)

(73) Assignee: NICHIA CORPORATION, Anan-shi (JP)

(21) Appl. No.: 18/991,854

(22) Filed: Dec. 23, 2024

(30) Foreign Application Priority Data
Dec. 26, 2023 (JP) 2023-219305

(51) Int. Cl. H01S 5/12; H01S 5/042; H01S 5/10; H01S 5/22

(52) U.S. Cl. CPC H01S 5/12; H01S 5/04256; H01S 5/1003; H01S 5/22

(57) ABSTRACT

A semiconductor laser element includes: a semiconductor layered portion including an active layer and having a waveguide structure, wherein the semiconductor layered portion includes: a first region including a diffraction grating, and a second region including a core region, and cladding regions located on both sides of the core region, the second region allowing laser light to propagate in a plurality of transverse modes. A width of the first region is greater than a width of the core region in a direction in which the core region and the cladding region are arranged. A current shielding structure is located at a position overlapping the first region in a top view, and includes one or more opening regions for injecting a current into the semiconductor layered portion in the first region. A total area of the one or more opening regions is smaller than an area of the first region in a top view.

### CROSS-REFERENCE TO RELATED APPLICATION

This application claims priority to Japanese Patent Application No. 2023-219305, filed on Dec. 26, 2023, the entire contents of which are incorporated herein by reference.

### BACKGROUND

The present disclosure relates to a semiconductor laser element.

In recent years, there is a demand for higher power in laser light from a semiconductor laser element. A high-power semiconductor laser element is used, for example, for a light source for processing. For example, Japanese Patent Publication No. JP 2011-151238 A (“Patent Document 1”) discloses a multi-transverse mode laser that can suppress optical damage on the stripe side.

### SUMMARY

Unfortunately, the semiconductor laser element disclosed in Patent Document 1 has insufficient power conversion efficiency and there is room for improvement.

An object of the present disclosure is to provide a semiconductor laser element having high power conversion efficiency.

A semiconductor laser element according to an embodiment of the present disclosure includes a semiconductor layered portion including an active layer and having a waveguide structure. The semiconductor layered portion includes (i) a first region including a diffraction grating, and (ii) a second region including a core region and cladding regions provided on both sides of the core region and allowing laser light to propagate in a plurality of transverse modes. A width of the first region is greater than a width of the core region in a direction in which the core region and the cladding region are arranged. A current shielding structure is provided at a position overlapping the first region in a top view, and includes one or more opening regions for injecting a current into the semiconductor layered portion in the first region. A total area of the one or more opening regions is smaller than an area of the first region in a top view.

Certain embodiments of the present disclosure can provide a semiconductor laser element having high power conversion efficiency.

### BRIEF DESCRIPTION OF THE DRAWINGS

FIG. 1 is a top view of a semiconductor laser element of a first embodiment according to the present disclosure.

FIG. 2 is a schematic top view of the region structure of the semiconductor laser element according to the first embodiment.

FIG. 3 is a schematic cross-sectional view taken along line III-III of the semiconductor laser element illustrated in FIG. 1.

FIG. 4 is a schematic cross-sectional view taken along line IV-IV of the semiconductor laser element illustrated in FIG. 1.

FIG. 5 is a diagram illustrating an overview of a method for measuring a beam waist radius W₀ and a beam divergence angle φ.

FIG. 6 is a schematic cross-sectional view of a first region of a semiconductor laser element of a second embodiment according to the present disclosure.

FIG. 7 is a schematic cross-sectional view of a first region of a semiconductor laser element of a third embodiment according to the present disclosure.

FIG. 8 is a schematic cross-sectional view of a first region of a semiconductor laser element of a fourth embodiment according to the present disclosure.

FIG. 9 is a top view of a semiconductor laser element of a modified example according to the present disclosure.

FIG. 10 is a top view of a semiconductor laser element of another modified example according to the present disclosure.

### DETAILED DESCRIPTION

Embodiments and modified examples for implementing a semiconductor laser element of the present disclosure are described below with reference to the drawings. Embodiments of the semiconductor laser element described below are intended to embody technical concepts of the present invention, but the present invention is not limited to the described embodiments unless otherwise specifically stated.

In each drawing, members having identical functions may be denoted by the same reference characters. In view of the ease of explanation or understanding of the main points, the embodiments, modified examples, or examples may be illustrated separately for convenience, but the partial substitutions or combinations of the configurations illustrated in different embodiments, modified examples, and examples are possible. In the embodiments, modified examples, and examples described below, descriptions of matters that are the same as those already described will be omitted, and only different points are described. In particular, similar actions and effects according to similar configurations shall not be mentioned sequentially in each embodiment, modified example, and example. The size, positional relationship, and the like of members illustrated in the drawings may be exaggerated to clarify explanation.

### Semiconductor Laser Element of Present Disclosure

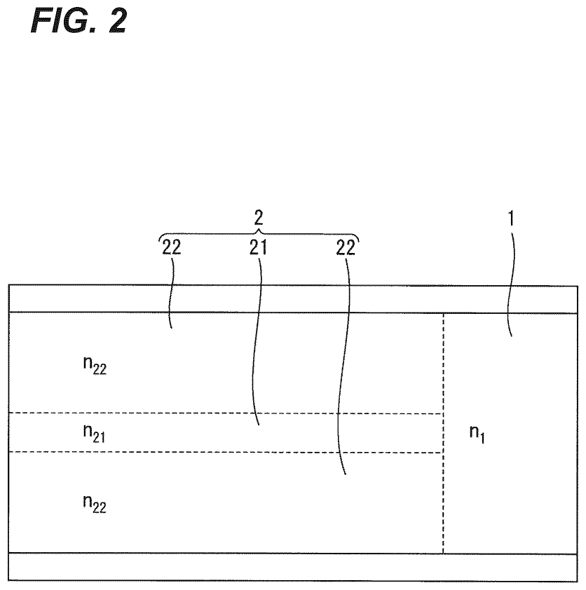

A semiconductor laser element of the present disclosure is a semiconductor laser element including a semiconductor layered portion 101 including an active layer 120 and having a waveguide structure illustrated in FIG. 2.

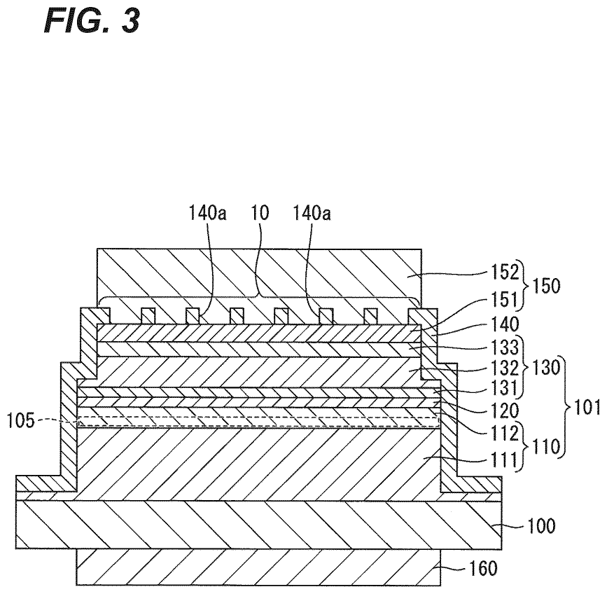

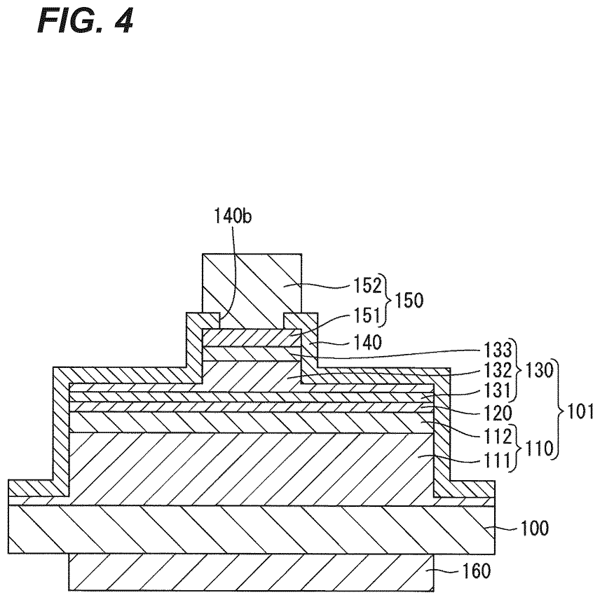

Specifically, as illustrated in FIGS. 3, 4, and the like, the semiconductor layered portion 101 in the semiconductor laser element of the present disclosure includes (i) a first region 1 including a diffraction grating 105 and (ii) a second region 2 including a core region 21 and cladding regions 22 provided on both sides of the core region 21 and allowing laser light to propagate in a plurality of transverse modes.

In addition, a width of the first region 1 is greater than a width of the core region 21 in the direction in which the core region 21 and the cladding region 22 are disposed. Moreover, a current shielding structure 10 is provided at a position overlapping the first region 1 in a top view, and has one or more opening regions 140a for injecting a current into the semiconductor layered portion in the first region 1. Moreover, a refractive index of the first region 1 is n₁, a refractive index of the core region 21 is n₂₁, and a refractive index of the cladding region 22 is n₂₂.

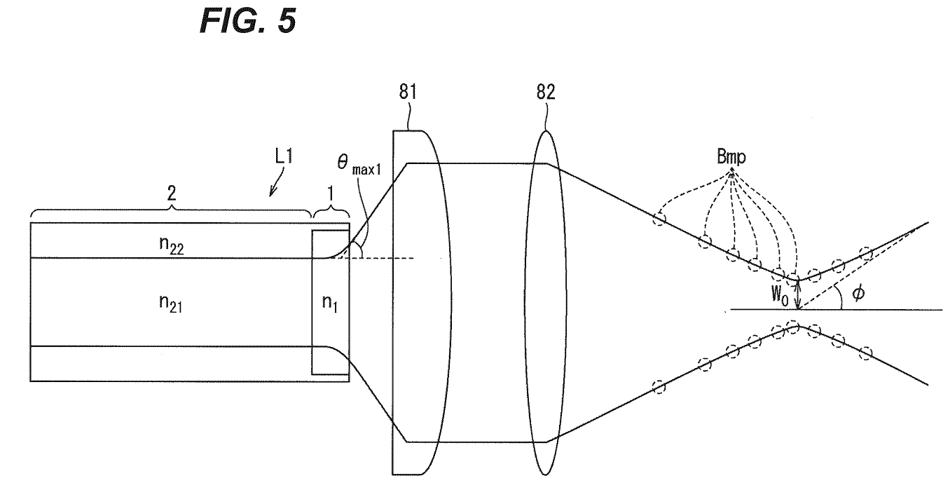

In a semiconductor laser element L1 including the first region 1 and the second region 2 configured as described above, laser light emitted from the second region 2 propagates, as illustrated in FIG. 5, through the first region 1 at a maximum diffusion angle Θₘₐₓ₁ determined by the refractive indices n₁, n₂₁, and n₂₂. The laser light emitted from the second region 2 propagates through the first region 1 at the maximum diffusion angle Θₘₐₓ₁ determined by the refractive indices n₁, n₂₁, and n₂₂, the laser light can be efficiently reflected by a diffraction grating 105 provided in the first region 1.

In the semiconductor laser element of the present disclosure, the total area of the one or more opening regions 140a is smaller than the area of the first region 1 in a top view.

By making the total area of the one or more opening regions 140a smaller than the area of the first region 1, the semiconductor laser element of the present disclosure can reduce the density of the current injected into the first region 1 and suppress the amount of heat generated in the first region 1 as compared with when the total area of the one or more opening regions 140a is not smaller than the area of the first region 1.

In this specification, the refractive index n₂₁ and the refractive index n₂₂ refer to effective refractive indices in consideration of optical confinement in the layered direction of the semiconductor layered portion. The refractive index n₁ refers to an effective refractive index obtained by averaging the refractive index modulation of the diffraction grating in consideration of optical confinement in the layered direction of the semiconductor layered portion. The maximum diffusion angle Θₘₐₓ₁ is equal to the maximum light-receiving angle of an optical waveguide in the second region 2.

For example, the semiconductor laser element is a multi-transverse-mode semiconductor laser element. Because the semiconductor laser element is a multi-transverse-mode semiconductor laser element, an effect of luminous efficiency improvement can be further obtained by reducing heat generation due to a reactive current in a portion which does not contribute to oscillation (propagation of light) as compared with a single-transverse-mode semiconductor laser element.

The semiconductor laser element of the present disclosure configured as described above can reduce the amount of heat generated in the first region 1, thereby increasing light emission power with respect to power consumption and efficiently obtaining high-power light.

The reason for this is described below in more detail.

First, the semiconductor laser element including the diffraction grating 105 in the first region 1 and the waveguide structure in the second region 2 performs laser oscillation according to, for example, the following principle. For example, light emitted by injecting a current into the core region 21 of the second region 2 propagates through a waveguide including the core region 21, enters the first region 1, and is reflected by the diffraction grating 105 provided in the first region 1 and returns to the second region 2. By repeating amplification of the light returned to the second region 2, the semiconductor laser element performs laser oscillation. In the semiconductor laser element L1 of the present disclosure, a coating may be applied to one or both of an end surface of the first region 1 on the side opposite to the second region 2 and an end surface of the second region 2 on the side opposite to the first region 1 for more effective laser oscillation. The semiconductor laser element may include an anti-reflection coating (AR-coating) provided on the end surface of the first region 1 on the side opposite to the second region 2 and a high-reflection coating (HR-coating) provided on the end surface of the second region 2 on the side opposite to the first region 1.

The inventors of the present disclosure have found that when current injection is performed in the entire first region 1, the entire first region 1 generates heat, leading to a decrease in power conversion efficiency.

Because the second region 2 is a region in which the light returned from the first region 1 is amplified to cause laser oscillation, a certain amount of current or more needs be injected, whereas the first region 1 has a main function of reflecting the light incident from the second region 2 by the diffraction grating 105 to return the light to the second region 2. Accordingly, the current injected into the first region 1 may be less than the current injected into the second region 2. Therefore, by making the total area of the one or more opening regions 140a for current injection in the first region 1 smaller than the area of the first region 1, the amount of heat generated in the first region 1 can be suppressed and power conversion efficiency can be increased.

### First Embodiment

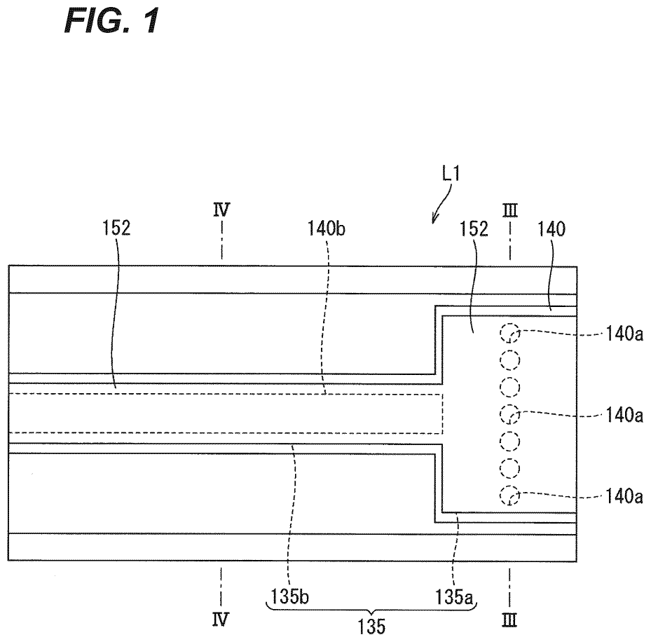

The semiconductor laser element L1 according to the first embodiment is described below with reference to FIGS. 1 to 4.

In the semiconductor laser element L1 of the first embodiment according to the present disclosure, the current shielding structure 10 is formed by an insulating film 140 provided on the semiconductor layered portion 101. By forming the current shielding structure 10 by the insulating film 140, the current shielding structure 10 is easily provided at a predetermined position on the semiconductor layered portion 101.

Specifically, as described below, the one or more opening regions 140a are provided in the insulating film 140 provided on the semiconductor layered portion 101 in the first region 1, and the amount of current injected into the semiconductor layered portion 101 in the first region 1 is suppressed by the opening regions 140a. The opening region 140a is, for example, circular. Because the opening region 140a is circular, the amount of current flowing through the opening region 140a can be made uniform.

The semiconductor laser element L1 of the first embodiment is described below in detail with reference to the drawings.

FIG. 1 is a top view of the semiconductor laser element L1 according to the first embodiment.

FIG. 2 is a schematic top view of the region structure of the semiconductor laser element L1 according to the first embodiment. FIG. 3 is a schematic cross-sectional view taken along line III-III of the semiconductor laser element L1 illustrated in FIG. 1. FIG. 4 is a schematic cross-sectional view taken along line IV-IV of the semiconductor laser element L1 illustrated in FIG. 1.

The semiconductor laser element L1 according to the first embodiment includes the semiconductor layered portion 101 provided on a substrate 100. For example, as illustrated in FIGS. 3 and 4, the semiconductor layered portion 101 includes:
(a) an n-side semiconductor layer 110 including an n-side cladding layer 111 and an n-side optical guiding layer 112;
(b) the active layer 120 provided on the n-side semiconductor layer 110; and
(c) a p-side semiconductor layer 130 provided on the active layer 120 and including a p-side optical guiding layer 131, a p-side cladding layer 132, and a p-side contact layer 133.

The semiconductor layered portion 101 includes, for example, a ridge 135 provided in the p-side contact layer 133 and the p-side cladding layer 132. The ridge 135 includes a first ridge 135a provided in the first region 1 and a second ridge 135b provided in the second region 2. In a top view, the first ridge 135a and the second ridge 135b are provided such that, for example, the center lines thereof coincide with each other in the traveling direction of the laser light.

In FIG. 1, because an outer lateral surface of the first ridge 135a and an outer lateral surface of the second ridge 135b are drawn to coincide with an outer lateral surface of a second electrode 152 to be described below. Therefore, in FIG. 1, the first ridge 135a and the second ridge 135b are drawn by broken lines drawn from the outer lateral surfaces of the first ridge 135a and the second ridge 135b.

Because the light emitted from the second region 2 and incident on the first region 1 spreads and propagates in the first region 1 as described above, the first ridge 135a is set wider than the second ridge 135b.

Moreover, an outer lateral surface of the first region 1 and the outer lateral surface of the first ridge 135a abut on each other, and the refractive index n₁ of the first region 1 does not change in the light propagation direction and the width direction and is constant.

In this specification, the width direction refers to a direction orthogonal to both the light propagation direction and the layered direction of the semiconductor layered portion 101.

On the semiconductor layered portion 101, a p-electrode 150 is provided in contact with the upper surface of the ridge 135. The p-electrode 150 includes a first electrode 151 and the second electrode 152, and the first electrode 151 is provided in contact with the p-side contact layer 133. As described below, in the first region 1, current injection into the first region 1 is suppressed by connecting the first electrode 151 and the second electrode 152 via the opening regions 140a of the insulating film 140. That is, in the first embodiment, the current shielding structure 10 is formed by the insulating film 140 provided in the first region 1.

Specifically, first, the first electrode 151 is provided in contact with, for example, the entire upper surface of the p-side contact layer 133 on the ridge 135 of the semiconductor layered portion 101. The insulating film 140 is provided on the p-side contact layer 133 via the first electrode 151. The insulating film 140 includes the one or more opening regions 140a located on the first ridge 135a and an opening portion 140b located on the second ridge 135b. The opening region 140a and the opening portion 140b are separated from each other, for example.

Note that in this specification, the terms “opening region” and “opening portion” do not indicate only a region surrounded by four sides. For example, a region sandwiched between two insulating films can be referred to as an opening region in the insulating film.

In the first embodiment, the second electrode 152 covers the opening region 140a and the opening portion 140b, and is connected to the first electrode 151 via the opening region 140a and the opening portion 140b. In the first embodiment, in the second region 2, because the width of the ridge is narrowed to form a waveguide structure, no current shielding function is required, and as illustrated in FIG. 4, in the second region 2, the width of the opening portion 140b is set to be substantially equal to the width of the second ridge 135b. On the other hand, in the first region 1, to suppress the amount of current to be injected, the total area of the one or more opening regions 140a is made smaller than the area of the first region 1 in a top view to form the current shielding structure 10. The first electrode 151 is, for example, ITO. As described above, the current injection into the p-side contact layer 133 in the first region 1 of the first embodiment is determined by parameters including the total area of the opening regions 140a provided in the insulating film 140, the contact resistance between the first electrode 151 and the second electrode 152, and the like. In other words, other parameters such as the total sum of the areas of the opening regions 140a provided in the insulating film 140 and the contact resistance between the first electrode 151 and the second electrode 152 can be appropriately adjusted so that heat generation due to a reactive current or the like in the first region 1 can be effectively reduced. For example, the total sum of the areas of the opening regions 140a provided in the insulating film 140 is preferably in a range from 0.04% to 0.22% of the area of the first region 1 in a top view. When the total sum is 0.04% or more, a current can be effectively supplied to the diffraction grating 105, and the diffraction grating 105 can have sufficient light transmittance. When the total sum is 0.22% or less, heat generation due to a reactive current or the like in the first region 1 can be effectively reduced. The total sum of the areas of the opening regions 140a provided in the insulating film 140 can be set in a range from 13.8 μm² to 207 μm². For example, the thickness of the first electrode 151 can be set in a range from 0.5 μm to 2 μm. With this value, a current can be effectively supplied to the diffraction grating 105.

The opening regions 140a may also be disposed along a straight line. By disposing the opening regions 140a along the straight line, a current can be uniformly supplied to the diffraction grating 105.

In the semiconductor laser element L1 according to the first embodiment, the width of the ridge 135 is set as follows so that the laser light propagates in a plurality of desired transverse modes.

First, the width of the second ridge 135b is set in the second region 2 so that the second region 2 includes the core region 21 having the refractive index n₂₁ and the cladding regions 22 provided on both sides of the core region 21 and each having the refractive index n₂₂. The second ridge 135b is provided in the central portion of the p-side semiconductor layer 130 of the second region 2 at a predetermined interval from both lateral surfaces of the second region 2 so that laser light is propagated in a plurality of desired transverse modes.

Thus, in the second region 2, the core region 21 having the refractive index n₂₁ is formed below the second ridge 135b, and the cladding regions 22 having the refractive index n₂₂ are formed on both sides of the core region 21, thereby forming the waveguide structure of the second region 2. In the semiconductor laser element L1 of the first embodiment, the width of the core region 21, that is, the width of the second ridge 135b, is set so that laser light including a plurality of desired transverse modes is propagated. The first electrode 151 is preferably in contact with an upper surface of the second ridge 135b without being in contact with an upper surface of the p-side cladding layer 132 on both sides of the second ridge 135b. With such a configuration, a current flowing through the cladding regions 22 can be reduced. In the semiconductor laser element L1 of the first embodiment, the first electrode 151 that abuts on the semiconductor layered portion 101 is provided at a position overlapping the insulating film 140 constituting the current shielding structure 10 in a top view. With such a configuration, the shape of the first electrode 151 is simplified, and the first electrode 151 is easily provided.

In the first embodiment, by providing the second ridge 135b, the core region is formed and the cladding regions are formed on both sides of the core region in a top view. However, for example, the second ridge 135b is not formed and a width of a current injection portion in the second region 2 is made smaller than the width of the entire second region 2, so that the core region and the cladding regions may be formed.

On the other hand, the first region 1 is not a region in which light incident from the second region 2 and propagated while spreading at the maximum diffusion angle Θₘₐₓ₁ is confined in a specific waveguide (core region 21). Therefore, as long as the light incident from the second region 2 can be propagated while spreading at the maximum diffusion angle Θₘₐₓ₁, the first ridge 135a is not an essential component in the first region 1. For example, the first ridge 135a may not be formed, and a portion of the semiconductor layered portion 101 excluding the second region 2 may be used as the first region 1. When the first ridge 135a is included, as illustrated in FIG. 3, for example, both lateral surfaces of the first ridge 135a can abut on both lateral surfaces of the first region 1. The width of the semiconductor layered portion 101 forming the first region 1 and the width of the first ridge 135a in the case in which the first ridge 135a is included are set so that the equivalent refractive indices with respect to the plurality of transverse modes of the laser light incident from the second region 2 to the first region 1 are substantially the same and the maximum diffusion angle Θₘₐₓ₁ of the laser light emitted from the second region 2 and incident on the first region 1 is taken into consideration so that the propagated light does not leak from the lateral surface of the semiconductor layered portion 101. Specifically, for example, in a cross section perpendicular to an optical axis of laser light, the width of the first region 1 is set so that both end portions of the first region 1 in the direction orthogonal to the layered direction of the semiconductor layered portion 101 are located outside imaginary lines spreading at the maximum diffusion angle Θₘₐₓ₁ from both ends of an emission end surface of the core region 21 on the first region 1 side.

The diffraction grating 105 is provided in the first region 1. The diffraction grating 105 is provided so that, for example, both ends of the diffraction grating 105 extend to both end portions of the first region 1.

Here, the cross-sectional shape of the ridge 135 may be a rectangular shape having a constant width as illustrated in FIGS. 3 and 4, or may be, for example, a trapezoidal shape in which the width decreases with increasing distance from the substrate 100, or an inverted trapezoidal shape in which the width increases with increasing distance from the substrate 100.

In the semiconductor laser element L1 according to the first embodiment of the present disclosure configured as described above, the width of the waveguide in the second region 2 is set so as to enable laser oscillation including a plurality of desired transverse modes, and the current shielding structure 10 is provided in the first region 1.

Thus, according to the semiconductor laser element of the first embodiment, laser light can be oscillated and propagated in a plurality of transverse modes, thereby providing the semiconductor laser element L1 having high power conversion efficiency.

Each component of the semiconductor laser element L1 according to the first embodiment is described below in detail with specific examples.

The semiconductor laser element L1 according to the first embodiment is not limited to the following specific examples as long as the semiconductor laser element L1 has a basic configuration that can obtain the above-described effects.

### Substrate 100

The substrate 100 of the semiconductor laser element L1 according to the first embodiment is, for example, a semiconductor substrate. The substrate 100 is, for example, a nitride semiconductor substrate such as a GaN substrate. The nitride semiconductor substrate may contain an n-type impurity. An element serving as the n-type impurity may be, for example, O, Si, or Ge. The nitride semiconductor substrate may be used as the substrate 100, and an upper surface thereof may be a+c plane (that is, a (0001) plane). In the first embodiment, the c plane is not limited to a plane exactly coinciding with the (0001) plane, but includes a plane having an off-angle of #1° or less, preferably +0.03° or less. The semiconductor laser element L1 may not include the substrate 100. As the upper surface of the substrate 100, an m plane, an a plane, an r plane, or the like may be used.

### Semiconductor Layered Portion 101

As described above, the semiconductor layered portion 101 may include, for example, the n-side semiconductor layer 110 including the n-side cladding layer 111 and the n-side optical guiding layer 112, the active layer 120 provided on the n-side semiconductor layer 110, and the p-side semiconductor layer 130 provided on the active layer 120 and including the p-side optical guiding layer 131, the p-side cladding layer 132, and the p-side contact layer 133.

The semiconductor layer of the semiconductor layered portion 101 is an III-V semiconductor layer. Examples of the group III-V semiconductor layer include a nitride semiconductor layer formed having a composition of In_{α}Al_{β}Ga_{1-α-β}N, (0≤α, 0≤β, α+β≤1).

Examples of the element serving as the n-type impurity used for the nitride semiconductor layer include Si and Ge. Further, examples of an element serving as a p-type impurity include Mg. Thus, the nitride semiconductor layer of each conductive type can be formed.

n-Side Semiconductor Layer 110

The n-side semiconductor layer 110 includes one or more semiconductor layers each containing an n-type impurity. The n-side semiconductor layer 110 may include, for example, the n-side cladding layer 111 having a refractive index n₁₁₁ and the n-side optical guiding layer 112 having a refractive index n₁₁₂. The n-side semiconductor layer 110 may further include an undoped layer that is intentionally undoped with impurities.

The refractive index n₁₁₁ and the refractive index n₁₁₂ are lower than a refractive index n₁₂₀ of the active layer 120. The refractive index n₁₁₁ and the refractive index n₁₁₂ are different from each other, and, for example, the refractive index n₁₁₁ is smaller than the refractive index n₁₁₂.

The n-side cladding layer 111 is disposed between the active layer 120 and the substrate 100. The n-side cladding layer 111 may be, for example, a nitride semiconductor layer. Examples of the nitride semiconductor include AlGaN and GaN. The film thickness of the n-side cladding layer 111 may be, for example, in a range from 0.45 μm to 3.0 μm. The n-type impurity content may be, for example, in a range from 1×10¹⁷ cm⁻³ to 5×10¹⁸ cm⁻³.

The n-side optical guiding layer 112 is disposed between the active layer 120 and the n-side cladding layer 111. The n-side optical guiding layer 112 may be, for example, a nitride semiconductor layer. Examples of the nitride semiconductor include AlGaN, GaN, and InGaN. The film thickness of the n-side optical guiding layer 112 may be, for example, in a range from 0.05 μm to 0.5 μm. The n-type impurity content may be, for example, in a range from 1×10¹⁷ cm⁻³ to 5×10¹⁸ cm⁻³.

### Active Layer 120

The active layer 120 is formed on the n-side optical guiding layer 112. The active layer 120 emits light having a wavelength in a range from 360 nm to 800 nm, for example. The active layer 120 may have a quantum well structure formed of one or more well layers and a plurality of barrier layers. The well layer and the barrier layer may be made of, for example, GaN, InGaN, AlGaN, or AlInGaN. The well layer is made of, for example, AlGaN, GaN, or InGaN, which is a nitride semiconductor having a band gap energy less than that of the barrier layer. The active layer 120 may have a multiple quantum well structure or a single quantum well structure. Note that any one or both of the well layer and the barrier layer may contain an impurity.

p-Side Semiconductor Layer 130

The p-side semiconductor layer 130 includes one or more semiconductor layers each containing a p-type impurity. The p-side semiconductor layer 130 is formed on the active layer 120. The p-side semiconductor layer 130 may include, for example, the p-side optical guiding layer 131 having a refractive index n₁₃₁, the p-side cladding layer 132 having a refractive index n₁₃₂, and the p-side contact layer 133 having a refractive index n₁₃₃ in this order from the substrate 100 side (that is, from the active layer 120 side). The p-side semiconductor layer 130 may include a layer other than these layers. The p-side semiconductor layer 130 may include an undoped layer that is not intentionally doped with impurities.

The refractive index n₁₃₁, the refractive index n₁₃₂, and the refractive index n₁₃₃ are lower than the refractive index n₁₂₀ of the active layer 120. The refractive index n₁₃₁, the refractive index n₁₃₂, and the refractive index n₁₃₃ may be different from one another. For example, the refractive index n₁₃₁ is higher than the refractive index n₁₃₂.

The p-side optical guiding layer 131 may be, for example, a nitride semiconductor layer. Examples of the nitride semiconductor include AlGaN and GaN. The film thickness of the p-side optical guiding layer 131 may be, for example, in a range from 0.05 μm to 0.25 μm. The p-side optical guiding layer 131 may be an undoped layer and may contain a p-type impurity in a range from 1×10¹⁶ cm⁻³ to 1×10¹⁸ cm⁻³, for example.

The p-side cladding layer 132 may be, for example, a nitride semiconductor layer. Examples of the nitride semiconductor include AlGaN and GaN. The p-side cladding layer 132 may have a single-layer structure or a multilayer structure in which nitride semiconductor layers having different compositions are layered. The p-type impurity content may be, for example, in a range from 1×10¹⁷ cm⁻³ to 1×10²⁰ cm⁻³. The p-side cladding layer 132 may not be provided. When the p-side cladding layer 132 is not provided, the amount of p-type impurities in the semiconductor layered portion 101 can be reduced, and the optical loss in the semiconductor layered portion 101 can be reduced.

The p-side contact layer 133 may be, for example, a nitride semiconductor. Examples of the nitride semiconductor include AlGaN and GaN. The p-side contact layer 133 may have a single-layer structure or a multilayer structure in which nitride semiconductor layers having different compositions are layered. The p-type impurity content may be in a range from 1×10¹⁹ cm⁻³ to 1×10²² cm⁻³.

### Waveguide Structure

The waveguide structure of the semiconductor laser element L1 according to the first embodiment is described below in detail.

The waveguide structure of the second region 2 is described first, and then the waveguide structure of the first region 1 is described.

The waveguide structure of the second region 2 includes the core region 21 having the refractive index n₂₁ and the cladding regions 22 located on both sides of the core region 21 and each having the refractive index n₂₂, and is a waveguide for propagating light in a plurality of transverse modes (that is, multi-transverse-mode) in the longitudinal direction of the core region 21. The number of transverse modes is determined by the width of the core region 21 and the difference between the refractive index n₂₁ of the core region 21 and the refractive index n₂₂ of the cladding regions 22 located on both sides of the core region 21. Here, the width of the core region 21 is a width in a direction perpendicular to the layered direction of the semiconductor layered portion 101 in a plane perpendicular to the optical axis of the waveguide. The thickness of the core region 21 is a thickness in the layered direction of the semiconductor layered portion 101 in a plane perpendicular to the optical axis of the waveguide. Although the cladding regions 22 are provided on both sides of the core region 21, the refractive indices of the two cladding regions 22 may be the same or different from each other. When the refractive indices of the two cladding regions 22 are different from each other, n_{22A} and n_{22B} can be used as the refractive indices of the two cladding region 22, and these values can be used as the refractive indices of the two cladding regions 22.

The number of transverse modes is described below.

In the following description, for the sake of simplicity, a symmetric three-layer flat waveguide is described. A number N of transverse modes of light propagating through the core region 21 can be set on the basis of the following Formula 1 by obtaining a standardized frequency V defined by the refractive index n₂₁ of the core region 21, the refractive index n₂₂ of the cladding regions 22, and the width of the core region 21.

$$V \geq N π / 2 \qquad ( Formula 1 )$$

(N is an integer of 1 or more)

Here, the standardized frequency V is expressed by V=k₀n₂₁a(2Δ)^{1/2}. k₀ is a wave number in a vacuum, a is a half width of the core region 21, and Δ (=(n₂₁²−n₂₂²)/(2n₂₁²)) is a relative refractive index difference.

For example, in Formula 1, N is the mode order of the transverse modes, and when the standardized frequency V is in a range from equal to or greater than π/2 to less than 2π/2 (that is, π), light can be propagated in two modes, a 0 order mode (basic mode) and a first order mode. When the standardized frequency V is in a range from equal to or greater than Nπ/2 and less than (N+1)π/2, light can be propagated in the 0 order, first order, second order, . . . , and Nth order, that is, a (N+1) plurality of modes.

In this manner, the number of transverse modes of light propagating through the second region 2 can be set on the basis of Formula 1. Specifically, the number of transverse modes can be set on the basis of the width of the second ridge 135b. Even in a semiconductor laser element having no ridge structure, the number of transverse modes can be similarly set on the basis of parameters constituting the waveguide.

The number of transverse modes is preferably as large as possible to achieve high power, and for example, is 10 or more, preferably 30 or more, more preferably 50 or more. The number of transverse modes is preferably as large as possible to achieve high power, but when the number is too large, there is a problem such as deterioration of light condensing properties, and the number is, for example, 500 or less, preferably 300 or less, more preferably 100 or less.

As can be understood from the above description of Formula 1, the number of transverse modes is determined by parameters including the width of the core region 21. In consideration of the number of transverse modes and the heat dissipation described above, the width of the core region 21 is, for example, in a range from 15 μm to 120 μm, more preferably in a range from 45 μm to 100 μm.

### Diffraction Grating 105

As illustrated in FIG. 1 and the like, the diffraction grating 105 is provided in the first region 1. The diffraction grating 105 is preferably provided in the entire first region 1. Also, the diffraction grating 105 is not provided in the second region 2. The Bragg wavelength in the diffraction grating is represented by the following Formula 2. Formula 2 indicates that the effective period of the diffraction grating is the product of the equivalent refractive index and the pitch of the diffraction grating.

$$Bragg wavelength {λ}_{B} = equivalent refractive index {n}_{1} \times pitch P of diffraction grating \times 2 \qquad ( Formula 2 )$$

The diffraction grating 105 can be formed by alternately (periodically) providing regions having different refractive indices in the light propagation direction. The diffraction grating 105 is, for example, provided between two adjacent semiconductor layers. The pitch of the diffraction grating 105 can be appropriately selected in consideration of the wavelength of light emitted from the active layer 120.

The equivalent refractive index n₁ of the diffraction grating 105 is substantially the same for each transverse mode, and thus the Bragg wavelength λ_{B} corresponding to each transverse mode is also substantially the same. Therefore, the full width at half maximum of the spectrum of the laser light emitted by the semiconductor laser element L1 can be reduced as compared with the case in which the equivalent refractive index n₁ of the diffraction grating 105 is different for each transverse mode. For example, the full width at half maximum of the spectrum of the laser light emitted by the semiconductor laser element L1 is in a range from 0.01 nm to 0.5 nm. The equivalent refractive index n₁ of the diffraction grating 105 is the refractive index n₁ of the first region 1.

In the first embodiment, the diffraction grating 105 is provided, for example, between the n-side optical guiding layer 112 and the n-side cladding layer 111. Specifically, the diffraction grating 105 includes one or more first protrusion portions provided on the surface of the n-side cladding layer 111 and protruding toward the n-side optical guiding layer 112 and one or more second protrusion portions provided on the surface of the n-side optical guiding layer 112 and protruding toward the n-side cladding layer 111 alternately in the light traveling direction.

Here, the pitch (P) in Formula 2 is the sum of the length of one first protrusion portion and the length of one second protrusion portion in the light propagation direction.

In the first embodiment, although the diffraction grating 105 is provided between the n-side optical guiding layer 112 and the n-side cladding layer 111, it may be provided only in either the n-side optical guiding layer 112 or the n-side cladding layer 111 or may be provided between the n-side optical guiding layer 112 and the active layer 120. The diffraction grating 105 may be provided on the p-side semiconductor layer 130 side.

### Electrode

As illustrated in FIGS. 3 and 4, the semiconductor laser element L1 includes the p-electrode 150 and an n-electrode 160.

For example, when the substrate 100 has conductivity, the n-electrode 160 can be disposed on the lower surface of the substrate 100. When the substrate 100 has an insulating property, a part of the n-side cladding layer 111 is exposed and the n-electrode 160 can be formed on the exposed surface.

Examples of the material of the p-electrode 150 and the n-electrode 160 include a single-layer film or a multilayer film of a metal such as Ni, Rh, Cr, Au, W, Pt, Ti, and Al, an alloy thereof, conductive oxide including at least one selected from Zn, In, and Sn.

The p-electrode 150 may include a light-transmitting conductive film in contact with the ridge 135 as a first electrode. By selecting a material such that the refractive index of the light-transmitting conductive film is smaller than the refractive index of the active layer 120 and the refractive index of the p-side semiconductor layer 130, the light-transmitting conductive film can be treated as a p-side cladding layer. The light-transmitting conductive film is, for example, indium-tin oxide (ITO), indium-gallium-zinc oxide (IGZO), or the like. The insulating film 140 may be, for example, silicon oxide, aluminum oxide, aluminum nitride, or the like.

Calculation of Maximum Diffusion Angle Θₘₐₓ₁

In the semiconductor laser element L1 according to the first embodiment, the maximum diffusion angle Θₘₐₓ₁ to be referred to when setting the position of the current shielding structure 10 can be obtained by using a factor M² being an index given by the following Formula 3 and indicating the quality of a laser beam. The factor M² is an index indicating divergence from an ideal Gaussian beam, and is 1 for the ideal Gaussian beam. That is, when the factor M² of the laser light output from the semiconductor laser element L1 is known, how much the laser light spreads can be known as compared with the ideal Gaussian beam, and thus the maximum diffusion angle Θₘₐₓ₁ can be obtained.

$${M}^{2} = πφ {W}_{0} / λ \qquad ( Formula 3 )$$

W₀ is the beam waist radius, and φ is the beam divergence angle.

λ is the wavelength of laser light in a vacuum.

The beam waist radius W₀ and the beam divergence angle φ can be measured in the following manner using an optical system including a collimating lens 81 and a condenser lens 82 illustrated in FIG. 5.

The laser light emitted from the first region 1 is collimated by the collimating lens 81 and condensed by the condenser lens 82 to trace the locus of the condensed laser light. Specifically, the beam diameter of the condensed laser light is measured at various positions Bmp, the position where the beam diameter is the smallest is estimated, and the beam diameter (beam waist radius W₀) at that position is obtained. The divergence of the beam from the position where the beam diameter is the smallest is measured to determine the beam divergence angle φ. It should be noted that the definition of the parameters required for determining the factor M² is based on the International Organization for Standardization ISO 11146-1:2021 or ISO 11146-2:2021. The beam diameter is defined by D4σ (second moment width). The value of the current fed to the semiconductor laser element L1 when measuring the factor M² is within a predetermined operating current range.

The factor M² is calculated from Formula 3 using the beam waist radius W₀ and the beam divergence angle φ obtained as described above, and the maximum diffusion angle Θₘₐₓ₁ is obtained based on the factor M² as described above. The locus of the laser light emitted from the second region 2 can be found from the factor M² and the locus of the laser light measured in the process of obtaining the factor M². Thus, an imaginary line v1 spreading at the maximum diffusion angle Θₘₐₓ₁ from both ends of the emission end surface of the core region 21 is obtained. By comparing the positional relationship between the imaginary line and both ends of the first region 1, the spread of the laser light in the first region 1 can be examined. Here, as illustrated in FIG. 5 and the like, the maximum diffusion angle Θₘₐₓ₁ is an angle formed by a straight line obtained by removing a curved portion from the imaginary line and a straight line obtained by extending the boundary between the core region 21 and the cladding region 22.

Also, the factor M² of the laser light according to the first embodiment may be in a range from 2 to 100.

When the beam diameter of the laser light at the laser light emission end surface is smaller than the width of the first region 1 and the width of the first region 1 is substantially constant, it is apparent that both end portions of the first region 1 are located on the outer side of the imaginary line v1. Accordingly, the positional relationship between the width of the first region 1 and the imaginary line v1 can be found by first measuring the beam diameter of the laser light at the emission end surface of the laser light. With such a structure, variation in oscillation wavelength can be reduced.

In the first embodiment, the semiconductor laser element L1 according to the first embodiment has been described using a semiconductor laser element having a ridge structure as an example.

However, the semiconductor laser element L1 according to the first embodiment is not limited to a semiconductor laser element having a ridge structure and may be a rib-waveguide semiconductor laser element or an embedded-heterostructure-waveguide semiconductor laser element.

The semiconductor material constituting the semiconductor laser element described above may be a material other than a nitride semiconductor. The semiconductor material may be, for example, GaAs, InP, GaInP, GaInAsP, GaAlAs, or AlInGaP. In this case, a semiconductor laser element having an oscillation wavelength in a range from 760 nm to 1060 nm may be used. A semiconductor laser element made of material other than these materials may also be employed. For example, a semiconductor laser element that emits ultraviolet light may be made of aluminum nitride, boron nitride, or the like.

### Second Embodiment

A semiconductor laser element L2 according to the second embodiment is the same as the semiconductor laser element L1 according to the first embodiment in that the current shielding structure 10 forming a portion of the insulating film 140 is provided, but the structure of the p-electrode 150 is different.

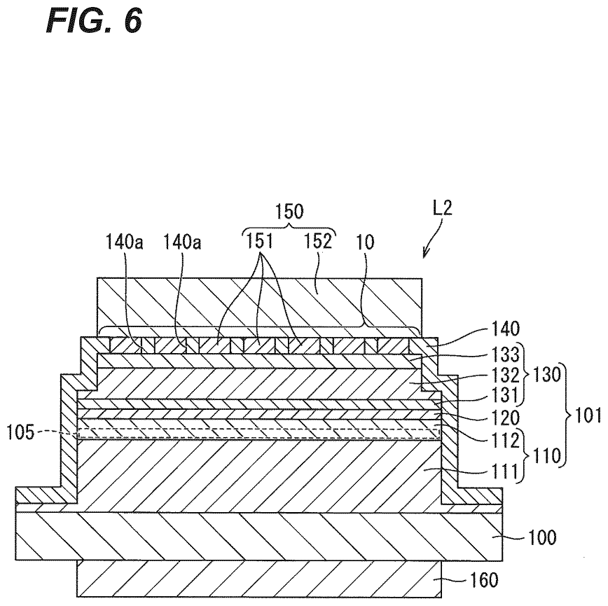

Specifically, in the semiconductor laser element L2 according to the second embodiment, in the first region 1, the first electrodes 151 are not in contact with the entire upper surface of the p-side contact layer 133 on the ridge 135 of the semiconductor layered portion 101, and as illustrated in FIG. 6, the first electrodes 151 are embedded in the opening regions 140a so that the first electrodes 151 are limited to the opening regions 140a and are in contact with the p-side contact layer 133.

That is, in the semiconductor laser element L2 according to the second embodiment, the first electrodes 151 that abut on the semiconductor layered portion 101 are not provided at positions overlapping the insulating film 140. With this configuration, the possibility that a current spreads in the lateral direction in the first electrode 151 is reduced, and the current can be shielded more effectively.

The semiconductor laser element L2 according to the second embodiment configured as described above can reduce a current injected into the first region 1, suppress a reactive current in the first region 1, and reduce heat generation.

Accordingly, in the semiconductor laser element L2 according to the second embodiment, laser light is oscillated and propagated in a plurality of transverse modes, so that high power can be obtained and a semiconductor laser element L2 having high power conversion efficiency can be provided.

In the semiconductor laser element L2 according to the second embodiment, the first electrodes 151 are embedded in the opening regions 140a and are in contact with the p-side contact layer 133 to be limited to the area of the opening regions 140a, so that the possibility that a current spreads in the lateral direction in the first electrodes 151 can be reduced as in the semiconductor laser element L1 according to the first embodiment, thereby shielding a current more effectively.

In the semiconductor laser element L2 according to the second embodiment, the structure of the p-electrode 150 in the second region 2 is not particularly limited and may be the same as that in the first embodiment, or the first electrode 151 may be embedded in the opening portion 140b.

The semiconductor laser element L2 according to the second embodiment has the same configuration as the semiconductor laser element L1 according to the first embodiment except for the p-electrode 150. For example, the semiconductor laser element L2 is a multi-transverse-mode semiconductor laser element.

### Third Embodiment

A semiconductor laser element L3 according to the third embodiment is different from the semiconductor laser element L1 according to the first embodiment in the configuration of a current shielding structure 13.

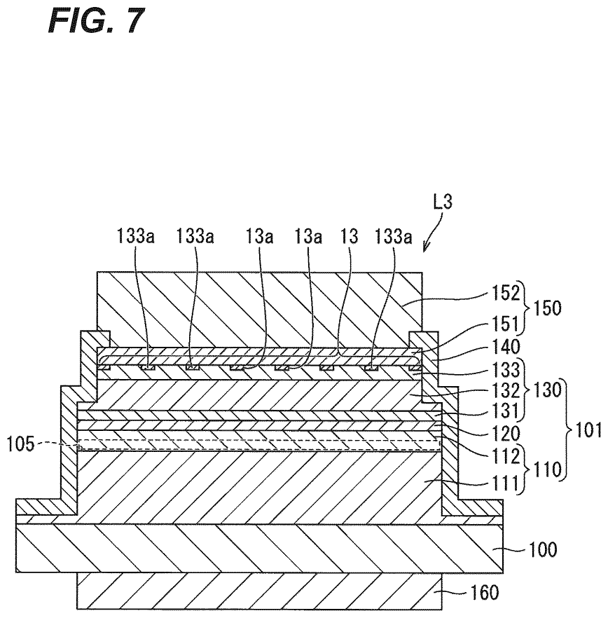

Specifically, as illustrated in FIG. 7, the current shielding structure 13 in the semiconductor laser element L3 according to the third embodiment is provided on the surface of the semiconductor layered portion 101 (surface of the p-side contact layer 133) and includes an oxide film 133a having one or more opening regions 13a, and a current is injected from the p-electrode 150 into the semiconductor layered portion 101 in the first region 1 via the opening regions 13a. The oxide film 133a is, for example, a film formed by oxidizing a part of the semiconductor layered portion 101. Because the current shielding structure 13 is formed of the oxide film 133a, a part of the semiconductor layered portion 101 can be used as an insulating structure, so that a separate insulating structure needs not be provided and thus the number of members can be reduced. The oxide film 133a is a film made of, for example, an oxide containing gallium and nitrogen.

In the semiconductor laser element L3 according to the third embodiment, for example, in the first region 1, the first electrode 151 can be in contact with the entire upper surface of the p-side contact layer 133 on the ridge 135 of the semiconductor layered portion 101.

In the semiconductor laser element L3 according to the third embodiment, the oxide film 133a constituting the current shielding structure 13 can be formed by, for example, oxidizing the surface of the p-side contact layer 133. In this manner, the first electrode 151 and the p-side contact layer 133 can be Schottky-joined via the oxide film 133a, and the current shielding structure 13 can be formed.

The semiconductor laser element L3 according to the third embodiment configured as described above can reduce the amount of current injected into the first region 1, suppress a reactive current in the first region 1, and reduce heat generation.

Accordingly, in the semiconductor laser element L3 according to the third embodiment, laser light is oscillated and propagated in a plurality of transverse modes, so that high power can be obtained and a semiconductor laser element L3 having high power conversion efficiency can be provided.

In the semiconductor laser element L3 according to the third embodiment, the current injection structure in the second region 2 is not particularly limited and may be the same as that in the first embodiment, or another structure may be employed.

For example, in the second region 2, a second oxide film provided on the semiconductor layer structure and having a continuous opening portion on the waveguide may be provided, and a current may be injected into the second region 2 through the opening portion. In this manner, in the second region 2, the core region 21 and the cladding regions 22 on both sides thereof can be provided, and light in a plurality of modes corresponding to the width of the opening portion can be oscillated.

In the semiconductor laser element L3 according to the third embodiment, the configuration of the semiconductor layered portion 101 and the like other than the current shielding structure 13 is the same as in the semiconductor laser element L1 according to the first embodiment. For example, the semiconductor laser element L3 is a multi-transverse-mode semiconductor laser element.

### Fourth Embodiment

A semiconductor laser element L4 according to the fourth embodiment is different from the semiconductor laser element L1 according to the first embodiment in the configuration of a current shielding structure 14.

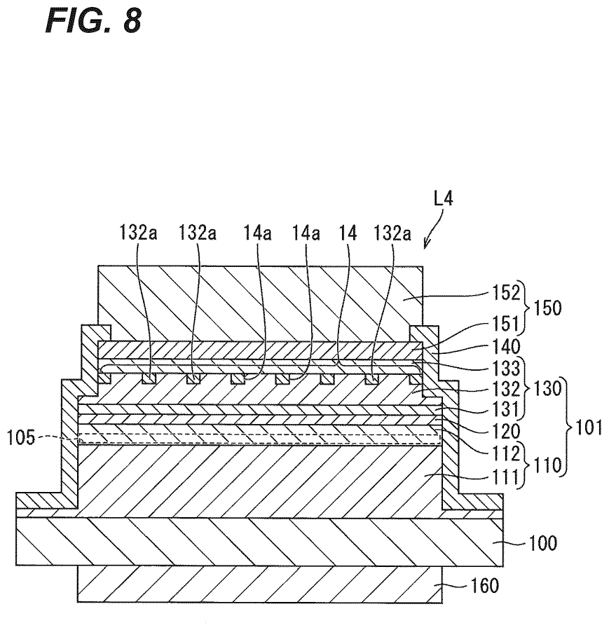

Specifically, as illustrated in FIG. 8, the current shielding structure 14 in the semiconductor laser element L4 according to the fourth embodiment is formed by a current blocking layer 132a provided in the p-side semiconductor layer 130 of the semiconductor layered portion 101 and having an opening region 14a in the first region 1, and is formed by limiting a current injected from the p-electrode 150 by the opening region 14a. The current blocking layer 132a is an undoped layer that does not substantially contain an impurity such as Si or Mg, and is a layer for shielding a current. By forming the current shielding structure 14 by the current blocking layer 132a, a structure for insulation can be provided at a predetermined position inside the p-side semiconductor layer 130.

In the semiconductor laser element L4 according to the fourth embodiment, for example, in the first region 1, the first electrode 151 can be in contact with the entire upper surface of the p-side contact layer 133 on the ridge 135 of the semiconductor layered portion 101. The current blocking layer 132a can be provided by forming an undoped layer in a part of the p-side semiconductor layer 130.

Although FIG. 8 illustrates an example in which the current blocking layer 132a is provided by making a part of the p-side cladding layer 132 undoped, the current blocking layer 132a may be provided on the active layer 120, that is, on the p-electrode 150 side, and may be provided, for example, in the p-side optical guiding layer 131 or the p-side contact layer 133. The current blocking layer 132a can be provided via an undoped layer as an additional layer in addition to the p-side optical guiding layer 131, the p-side cladding layer 132, and the p-side contact layer 133 on the p-side semiconductor layer 130.

The semiconductor laser element L4 according to the fourth embodiment configured as described above can limit the amount of current injected into the first region 1, suppress a reactive current in the first region 1, and reduce heat generation.

Accordingly, in accordance with the semiconductor laser element L4 according to the fourth embodiment, laser light can be oscillated and propagated in a plurality of transverse modes, so that high power can be obtained and a semiconductor laser element L4 having high power conversion efficiency can be provided.

In the semiconductor laser element L4 according to the fourth embodiment, the current injection structure in the second region 2 is not particularly limited and may be the same as that in the first embodiment, or another structure may be employed.

For example, in the second region 2, a current blocking layer provided on the semiconductor layer structure and having an opening portion on the waveguide may be provided, and a current may be injected into the second region 2 through the opening portion. In this manner, in the second region 2, the core region 21 and the cladding regions 22 on both sides thereof can be provided, and light in a plurality of modes corresponding to the width of the opening portion can be oscillated.

In the semiconductor laser element L4 according to the fourth embodiment, the configuration of the semiconductor layered portion 101 and the like other than the current shielding structure 14 is the same as in the semiconductor laser element L1 according to the first embodiment. For example, the semiconductor laser element L4 is a multi-transverse-mode semiconductor laser element.

In the above description of the embodiment, an example in which a plurality of opening regions 140a constituting the current shielding structure 10 are provided has been illustrated and described.

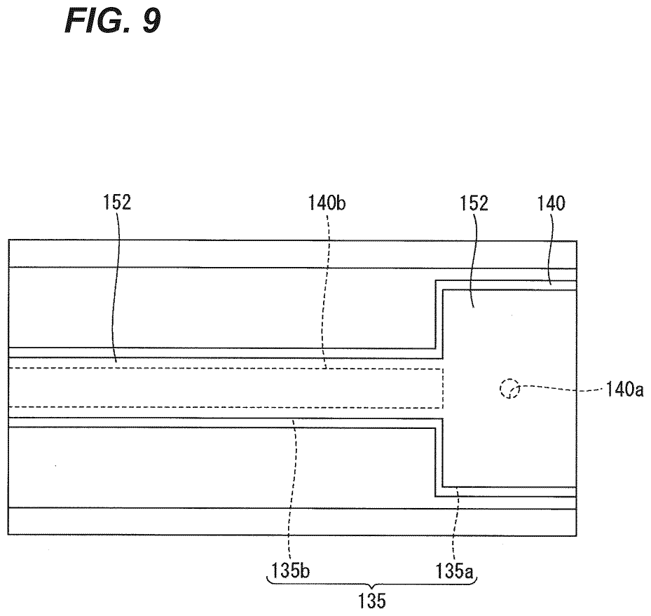

However, at least one opening region 140a constituting the current shielding structure 10 may be provided. When one opening region 140a or a reduced number of opening regions 140a are provided in this manner, for example, as illustrated in FIG. 9, the opening region 140a is preferably provided in a central portion of the first region 1 (region in which high-intensity light of light incident from the second region 2 propagates). In this case, the area of the opening region 140a is in a range from 25 μm² to 150 μm².

Although the opening regions 140a of the first and second embodiments are illustrated and described in FIG. 9, at least one opening region 140a may be similarly provided for the opening region 13a of the third embodiment and the opening region 14a of the fourth embodiment.

In the above description of the embodiment, an example in which the opening region 140a constituting the current shielding structure 10 is circular in a top view has been illustrated and described. As described above, because the opening region 140a has a circular shape, the amount of current flowing through the opening region 140a can be made uniform.

However, the shape of the opening region 140a is not limited to the circular shape, and may be various shapes. For example, the shape of the opening region 140a may be a polygon such as a rectangle, or may be an ellipse.

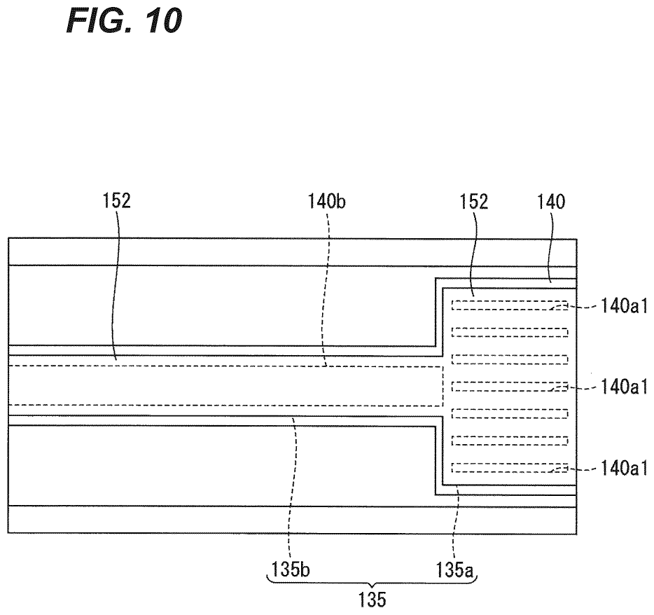

For example, FIG. 10 illustrates an example in which an opening region 140al having a rectangular shape is provided in a strip shape instead of the opening region 140a having a circular shape in a top view. FIG. 10 illustrates an example in which a plurality of opening regions 140al each having a rectangular shape in a top view are provided such that long axes thereof are parallel to each other; however, for example, the opening regions 140al each having a rectangular shape in a top view may be provided such that the long axes thereof are radially widened as being away from the second region. When the opening region 140a has a rectangular shape, the opening region 140a can be easily provided.

In FIG. 10, the plurality of opening regions 140al are distributed over the entire first region 1; however, the plurality of opening regions 140al may be provided in a strip shape only in the central portion of the first region 1 (region in which high-intensity light of light incident from the second region 2 propagates). In this manner, one or more opening regions 140a may be provided only in a region inside an imaginary line spreading at the maximum diffusion angle Θₘₐₓ₁ of the first region 1. This configuration can reduce a current flowing in a region of the first region 1 where no light propagates.

In addition, the number of opening regions 140al provided may be reduced as compared with the case in which the opening regions 140a are provided in the entire first region 1, and in this case, the opening regions 140al provided in a reduced number are preferably provided in the central portion of the first region 1 (region in which high-intensity light of light incident from the second region 2 propagates).

Although the embodiment and the modified examples of the present disclosure have been described above, various modifications are possible as long as the configuration based on the technical ideas of the present disclosure is included. In addition, various changes can be made to the combination and order of the components in the embodiment and the modified examples within the scope and spirit of the present disclosure.

### REFERENCE CHARACTER LIST

L1, L2, L3, L4 Semiconductor laser element
1 First region
2 Second region
10, 13, 14 Current shielding structure
21 Core region
22 Cladding region
100 Substrate
101 Semiconductor layered portion
150 p-electrode
151 First electrode
152 Second electrode
160 n-electrode
110 n-side semiconductor layer
111 n-side cladding layer
112 n-side optical guiding layer
120 Active layer
130 p-side semiconductor layer
131 p-side optical guiding layer
132 p-side cladding layer
132a Current blocking layer
133 p-side contact layer
133a Oxide film
105 Diffraction grating
135 Ridge
135a First ridge
135b Second ridge
140 Insulating film
140a Opening region
140b Opening portion

1. A semiconductor laser element comprising:
a semiconductor layered portion comprising an active layer and having a waveguide structure, wherein the semiconductor layered portion comprises:
a first region comprising a diffraction grating, and
a second region comprising a core region, and cladding regions located on both sides of the core region, the second region allowing laser light to propagate in a plurality of transverse modes, wherein:
a width of the first region is greater than a width of the core region in a direction in which the core region and the cladding region are arranged,
a current shielding structure is located at a position overlapping the first region in a top view, and comprises one or more opening regions for injecting a current into the semiconductor layered portion in the first region, and
a total area of the one or more opening regions is smaller than an area of the first region in a top view.

2. The semiconductor laser element according to claim 1, wherein:
laser light emitted from the second region propagates through the first region at a maximum diffusion angle Θₘₐₓ₁ determined by a refractive index n₁ of the first region, a refractive index n₂₁ of the core region, and a refractive index n₂₂ of the cladding region.

3. The semiconductor laser element according to claim 1, wherein:
the one or more opening regions are circular.

4. The semiconductor laser element according to claim 1, wherein:
the one or more opening regions are rectangular.

5. The semiconductor laser element according to claim 1, wherein:
the current shielding structure comprises an insulating film located on the semiconductor layered portion.

6. The semiconductor laser element according to claim 1, wherein:
the current shielding structure comprises an oxide film located on a surface of the semiconductor layered portion.

7. The semiconductor laser element according to claim 1, wherein:
the current shielding structure comprises a current blocking layer located in the semiconductor layered portion.

8. The semiconductor laser element according to claim 1, further comprising:
an electrode abutting on the semiconductor layered portion, the electrode being in contact with the semiconductor layered portion, wherein:
the electrode is located at a position overlapping the current shielding structure in a top view.

9. The semiconductor laser element according to claim 1, further comprising:
an electrode abutting on the semiconductor layered portion, the electrode being in contact with the semiconductor layered portion, wherein:
the electrode is not provided at a position overlapping the current shielding structure in a top view.
